(19) United States
(12) Patent Application Publication
(10) Pub. No.: US 2005/0274497 A1
(43) Pub. Date: Dec. 15, 2005

(54) Heat dissipation module with noise reduction functionality

(76) Inventors: Yu-Nien Huang, Chung Li City (TW); Tsan-Nan Chien, Taipei City (TW); Cheng-Yu Wang, Hsinchu City (TW); Shun-Ta Yu, Taipei City (TW)

Correspondence Address: RABIN & BERDO, P.C., Suite 500, 1101 14 Street, N.W., Washington, DC, 20005, US

(21) Appl. No.: 11/055,657

(22) Filed: Feb. 11, 2005

(30) Foreign Application Priority Data
Jun. 11, 2004 (TW) 93116912

(51) Int. Cl. H05K 7/20

(52) U.S. Cl. 165/121; 361/697

(57) ABSTRACT

A dissipation module has a dissipation fin module and a centrifugal fan. The centrifugal fan outputs airflow towards the dissipation fin module to remove the heat from it. The centrifugal fan includes a centrifugal impeller mounted on a motor. An outer housing houses the motor and the centrifugal impeller. Convex members or concave portions are formed on an inner wall of the housing outlet so as to reduce noise. The dissipation fin module includes a fin set closely attached to a heat source, as well as an airflow channel housing. Convex members or concave portions are also formed on an inner wall of the airflow channel for reducing noise.

### RELATED APPLICATIONS

The present application is based on, and claims priority from, Taiwan Application Serial Number 93116912, filed Jun. 11, 2004, the disclosure of which is hereby incorporated by reference herein in its entirety.

### BACKGROUND

1. Field of Invention

The present invention relates to a heat dissipation module. More particularly, the present invention relates to a heat dissipation module with noise reduction functionality.

2. Description of Related Art

As a notebook PC becomes thinner, there is less and less space for heat convection and heat dissipation design inside the case housing of the notebook PC. When it comes to high-frequency components, such as the CPU (central processing unit) and graphics processing chip, the heat dissipation design hits a bottleneck. Thus, the mainstream framework of heat dissipation design is forced heat convection via a centrifugal fan.

FIG. 1 illustrates a perspective view of a conventional centrifugal fan. A centrifugal fan 10 includes a spiral-shaped flow channel design. A centrifugal impeller 16 transforms air dynamic energy into static pressure so as to overcome high flow impedance inside the case housing of the notebook PC. Air driven by the centrifugal impeller 16 flows through the spiral-shaped flow channel 14 and generates a wake flow and a vortex, which create high-frequency and narrow-band noise. Airflow 18 accompanied by the noise goes out of an outlet and enters a dissipation fin set 22, attached to a heat source 20, thereby creating even more high-frequency noise due to friction between airflow and an inner wall of the dissipation fin set 22.

Once heat dissipation efficiency is enhanced, airflow is essentially accelerated. The stronger the airflow is, the more turbulent the wake flow is.

Thus, a notebook PC manufacturer faces a challenge between noise reducing and heat dissipation efficiency improving.

### SUMMARY

It is therefore an objective of the present invention to provide a heat dissipation module with noise reduction functionality.

In accordance with the foregoing and other objectives of the present invention, a dissipation module has a dissipation fin module and a centrifugal fan.

The centrifugal fan outputs airflow towards the dissipation fin module to remove the heat from it. The centrifugal fan includes a centrifugal impeller mounted on a motor. An outer housing houses the motor and the centrifugal impeller.

Convex members or concave portions are formed on an inner wall of the housing outlet so as to reduce noise. The dissipation fin module includes a fin set closely attached to a heat source, as well as an airflow channel housing. Convex members or concave portions are also formed on an inner wall of the airflow channel for reducing noise.

Thus, the dissipation module with noise reduction not only decreases noise amplitudes, but also stabilizes the wake flow. Namely, the airflow with widespread Haystack noise will make a listener feel more comfortable.

It is to be understood that both the foregoing general description and the following detailed description are by examples and are intended to provide further explanation of the invention as claimed.

### BRIEF DESCRIPTION OF THE DRAWINGS

The accompanying drawings are included to provide a further understanding of the invention and are incorporated in and constitute a part of this specification. The drawings illustrate embodiments of the invention and, together with the description, serve to explain the principles of the invention. In the drawings,

FIG. 1 illustrates a perspective view of a conventional centrifugal fan;

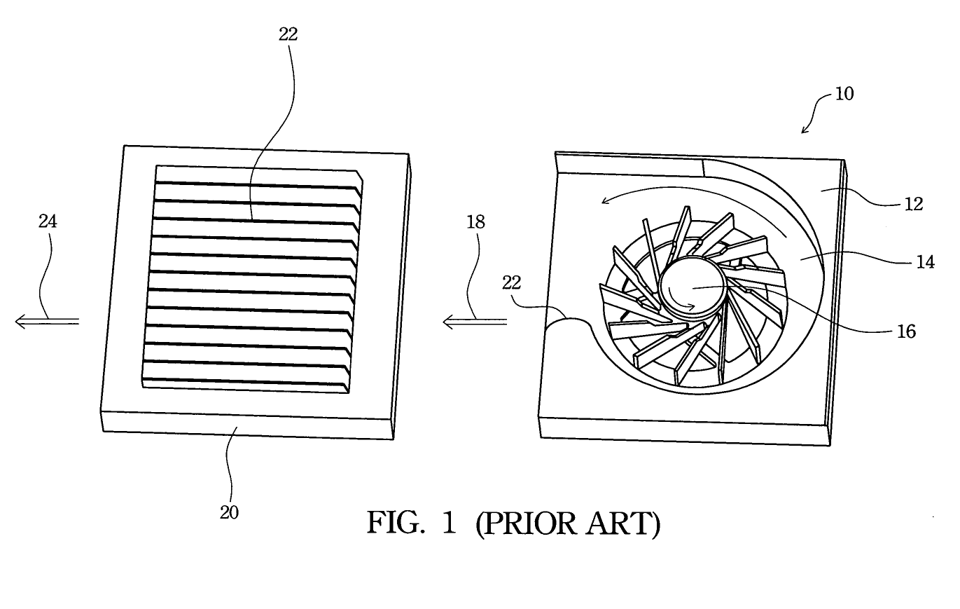

FIG. 2 illustrates a perspective view of a dissipation module with a noise reduction function according to one preferred embodiment of this invention;

FIG. 2A illustrates a cross sectional view of a dissipation module with a noise reduction function according to one preferred embodiment of this invention;

FIG. 2B illustrates a perspective view of an inner sidewall of an airflow channel housing according to one preferred embodiment of this invention; and

FIGS. 3A-3D respectively illustrate enlarged views of different inner sidewall designs of an airflow channel housing according to another preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In order to reduce noise caused by strong airflow, the present invention discloses a heat dissipation module with a noise reduction function. By forming convex members or concave portions on an inner sidewall of a centrifugal fan outlet, noise can be reduced. The convex members or concave portions can also be formed on an inner sidewall of an airflow channel, such as a dissipation fin set, to reduce noise.

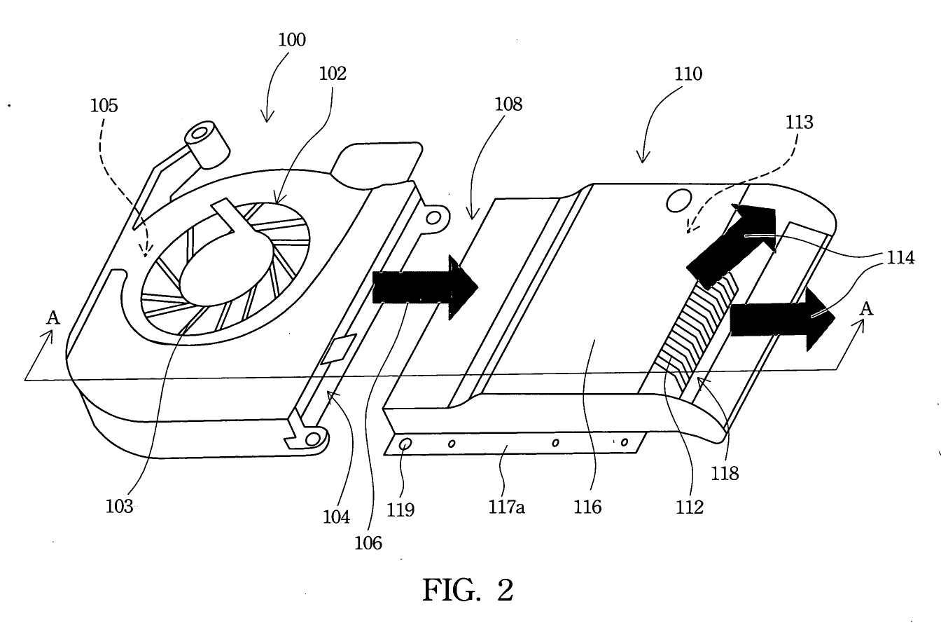

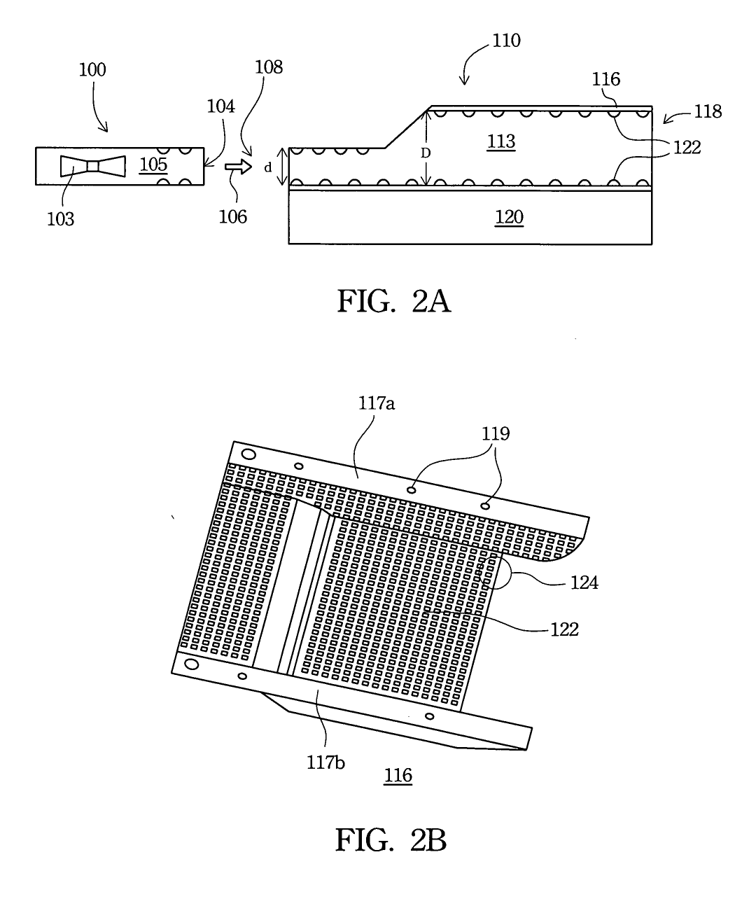

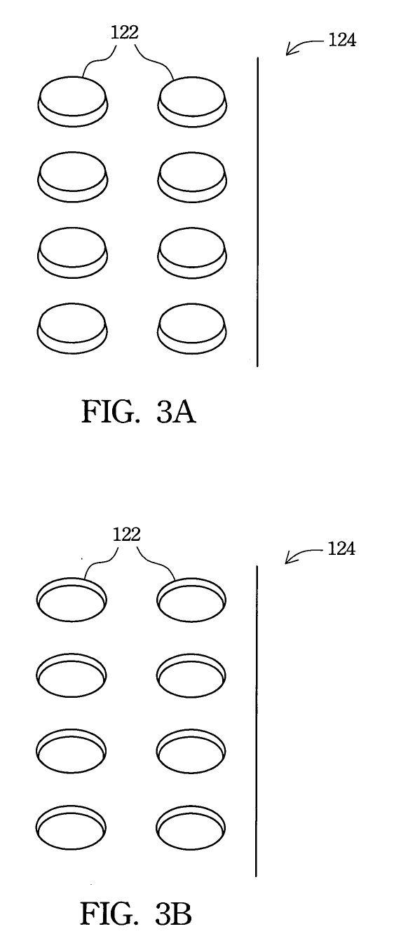

FIG. 2 illustrates a perspective view of a dissipation module with a noise reduction function according to one preferred embodiment of this invention. This preferred embodiment includes a centrifugal fan 100 and a heat dissipation fin module 110. The centrifugal fan 100 has a centrifugal impeller 103. A motor (not illustrated in FIG. 2) of the centrifugal fan 100 can drive the centrifugal impeller 103 to introduce air from an inlet 102 via a spiral-shaped flow channel 105 towards outlet 104. Due to the friction between air and an inner wall of the spiral-shaped flow channel 105, an airflow 106 contains several specific high-frequency and narrow-band noises. The heat dissipation fin module 110 is often installed close to a heat source component 120 (shown in FIG. 2A) so that heat generated by the component 120 can be transferred via the heat dissipation fin set 112. The heat dissipation fin module 110 consists of the heat dissipation fin set 112 and an airflow channel housing 116. The airflow channel housing 116 has several screw holes 119 on securing flanges 117a and 117b (shown in FIG. 2B) at two sides for mounting. The heat dissipation fin module 110 has an inlet 108 to receive the airflow 106 from the centrifugal fan 100. The airflow 106 passes by the heat dissipation fin set 112 to take away heat from it and then passes out of the outlet 118.

FIG. 2A illustrates a cross-sectional view taken along the line A-A in FIG. 2. This preferred embodiment discloses many convex members or concave portions 122 formed in airflow channel 113 of the heat dissipation fin module 110. The convex members or concave portions 122 can be formed on inner walls of the airflow channel 113 to perform a noise reduction function. The convex members or concave portions 122 have a noise reduction function, which not only makes the airflow near the sidewall smooth, but also breaks noise caused by airflow hitting the sidewall. Moreover, the convex members or concave portions 122 can absorb or interfere with the noise. The convex members or concave portions 122 can also be formed on an inner wall of the outlet 104. The convex members or concave portions 122 should be designed as small size, i.e., depths of concave portions 122 or heights of convex members 122 are small enough in comparison with inner, cross-sectional diameter (D, d) of the airflow channel 113 so that concave portions or convex members 122 do not affect the airflow speed. The convex members or concave portions are effective in reducing high-frequency noise, and airflow channel cross-sectional area is an important factor. For common design, an inner, cross-sectional diameter (D, d) is 0.5 to 1.0 times the noise wavelength (referring to FIG. 2A).

FIG. 2B illustrates a perspective view of an inner sidewall of an airflow channel housing according to one preferred embodiment of this invention. The convex members or concave portions 122 have a noise reduction function, which not only makes the airflow near the sidewall smooth, but also breaks noise caused by airflow hitting the sidewall. Moreover, the convex members or concave portions 122 can absorb or interfere with the noise. The airflow channel housing 116 has several screw holes 119 on securing flanges 117a and 117b at two sides for mounting on the heat dissipation fin module 110.

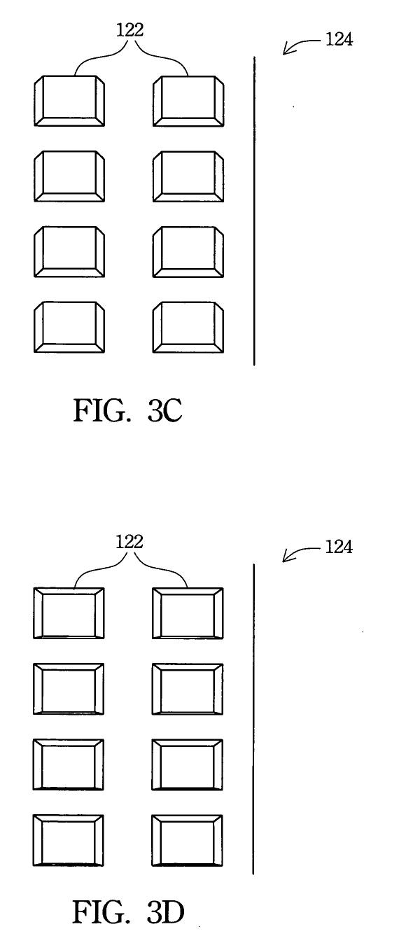

FIGS. 3A-3D respectively illustrate detailed views (enlarged views of reference number 124 in FIG. 2B) of different inner sidewall designs of an airflow channel housing according to another preferred embodiment of this invention. FIG. 3A illustrates a design of circular convex members. FIG. 3B illustrates a design of circular concave portions. FIG. 3C illustrates a design of rectangular convex members. FIG. 3D illustrates a design of rectangular concave portions.

According to the preferred embodiments, the dissipation module with noise reduction not only decreases noise amplitudes, but also stabilizes the wake flow. Namely, the airflow with widespread Haystack noise will make a listener feel more comfortable.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A heat dissipation module with a noise reduction function, comprising:
a dissipation fin set, closely attached to a heat source; and
an airflow channel housing, securing said dissipation fin set and the heat source inside, said airflow channel housing comprising:
an inlet, receiving an airflow towards said dissipation fin set;
an outlet, outputting the airflow from said dissipation fin set;
inner sidewalls, defining an airflow channel for guiding the airflow from said inlet to said outlet; and
a plurality of concave portions or convex members, formed on said inner sidewalls, reducing noises in the airflow.

2. The heat dissipation module of claim 1, wherein said concave portions are circular or rectangular.

3. The heat dissipation module of claim 1, wherein said convex members are circular or rectangular.

4. The heat dissipation module of claim 1, wherein an inner, cross-sectional diameter of said airflow channel is 0.5-1.0 times the noise wavelength.

5. The heat dissipation module of claim 4, wherein depths of said concave portions are small enough in comparison with said inner, cross-sectional diameter of said airflow channel so that said concave portions do not affect the airflow speed.

6. The heat dissipation module of claim 4, wherein heights of said convex members are small enough in comparison with said inner, cross-sectional diameter of said airflow channel so that said convex members do not affect the airflow speed.

7. A heat dissipation module with a noise reduction function, comprising:
a centrifugal impeller;
an outer housing, wherein said centrifugal impeller is housed inside, said outer housing comprising:
a first inlet, positioned along an axial direction of said centrifugal impeller;
a first outlet, positioned along a radial direction of said centrifugal impeller, wherein said centrifugal impeller drives the airflow from said inlet to said first outlet; and
a plurality of first concave portions or convex members, formed on an inner sidewall of said second outlet, reducing noises in the airflow;
a dissipation fin set, closely attached to a heat source; and
an airflow channel housing, securing said dissipation fin set and the heat source inside, said airflow channel housing comprising:
a second inlet, receiving the airflow from said first outlet towards said dissipation fin set;
a second outlet, outputting the airflow from said dissipation fin set;
inner sidewalls, defining an airflow channel for guiding the airflow from said second inlet to said second outlet; and
a plurality of second concave portions or convex members, formed on said inner sidewalls, reducing noises in the airflow.

8. The heat dissipation module of claim 7, wherein said first concave portions are circular or rectangular.

9. The heat dissipation module of claim 7, wherein said first convex members are circular or rectangular.

10. The heat dissipation module of claim 7, wherein said second concave portions are circular or rectangular.

11. The heat dissipation module of claim 7, wherein said second convex members are circular or rectangular.

12. The heat dissipation module of claim 7, wherein an inner, cross-sectional diameter of said airflow channel is 0.5-1.0 times the noise wavelength.

13. The heat dissipation module of claim 12, wherein depths of said concave portions are small enough in comparison with said inner, cross-sectional diameter of said airflow channel so that said concave portions do not affect the airflow speed.

14. The heat dissipation module of claim 12, wherein heights of said convex members are small enough in comparison with said inner, cross-sectional diameter of said airflow channel so that said convex members do not affect the airflow speed.

15. The heat dissipation module of claim 7, wherein an inner, cross-sectional diameter of said first outlet is 0.5-1.0 times the noise wavelength.

16. The heat dissipation module of claim 15, wherein depths of said concave portions are small enough in comparison with said inner, cross-sectional diameter of said first outlet so that said concave portions do not affect the airflow speed.

17. The heat dissipation module of claim 15, wherein heights of said convex members are small enough in comparison with said inner, cross-sectional diameter of said first outlet so that said convex members do not affect the airflow speed.
